(19) United States
(12) Patent Application Publication
(10) Pub. No.: US 2013/0306361 A1
(43) Pub. Date: Nov. 21, 2013

(54) TRANSPARENT ELECTRODE AND ELECTRONIC MATERIAL COMPRISING THE SAME

(71) Applicant: SAMSUNG ELECTRO-MECHANICS CO., LTD., Suwon (KR)

(72) Inventors: Woon Chun KIM, Suwon (KR); Jae Il Kim, Suwon (KR); Kang Heon Hur, Suwon (KR)

(21) Appl. No.: 13/890,644

(22) Filed: May 9, 2013

(30) Foreign Application Priority Data
May 15, 2012 (KR) 10-2012-0051552

(51) Int. Cl. H05K 1/09

(52) U.S. Cl. CPC H05K 1/097
USPC 174/257

(57) ABSTRACT

A transparent electrode includes: a substrate, a first electrode layer formed on the substrate, and a graphene oxide layer formed on and/or under the first electrode layer, and an electronic material for same. The transparent electrode includes graphene oxide layers on and under a conductor and/or a semiconductor to maintain a resistance measured on a surface of a graphene oxide layer in a transparent electrode including the graphene oxide layer almost equal to a resistance of a conductor and/or a semiconductor while showing characteristics of an insulator between conductors or semiconductors or between a conductor and a semiconductor which are separated from each other. Further, the graphene oxide layer performs a role of a barrier layer to protect the transparent electrode, thus preventing deterioration of characteristics of the transparent electrode and improving long-term reliability and transmittance.

### CROSS-REFERENCE TO RELATED APPLICATIONS

Claim and incorporate by reference domestic priority application and foreign priority application as follows:

“Cross Reference to Related Application

This application claims the benefit under 35 U.S.C. Section 119 of Korean Patent Application Serial No. 10-2012-0051552, entitled filed May 15, 2012, which is hereby incorporated by reference in its entirety into this application.”

### BACKGROUND OF THE INVENTION

1. Field of the Invention

The present invention relates to a transparent electrode and an electronic material comprising the same.

2. Description of the Related Art

In general, since various devices such as display devices, light emitting diodes, and solar cells transmit light to form images or generate electric power, they use a transparent electrode, which can transmit light, as an essential component. The transparent electrode consists of a thin film which satisfies the conditions of a specific resistance of less than 1×10⁻³ Ω/cm, a surface resistance of less than 10³ Ω/sq, and a transmittance of more than 80% in a visible light region of 380 to 780 nm.

Indium tin oxide (ITO) is most well known and widely used as a material of the transparent electrode. However, ITO has disadvantages such as high manufacturing costs due to a manufacturing process in a vacuum during manufacture of a thin film and increased resistance and reduced life due to cracks occurred when the device is bent or folded. Further, as consumption of indium is increased, economic efficiency is deteriorated due to rising prices. As global reserves of indium are reduced and chemical and electrical defects of the transparent electrode made of indium have been known, there are active efforts to search for electrode materials which can replace indium.

In addition, electronic devices and semiconductor devices use silicon as an active layer. Silicon has a carrier mobility of about 1,000 cm2/Vs at room temperature, but it is needed to use new materials, which can replace silicon, for manufacture of faster and better devices.

In recent times, various researches using graphene as a transparent electrode for replacing the ITO transparent electrode have been carried out. Graphene has a very transparent property even in an ultraviolet region as well as in a visible ray region and can implement a very thin electrode unlike ITO. It is possible to overcome heat emission, which is the most significant problem in light emitting devices, through high heat conductivity of graphene.

Graphene, a single layer of graphite, is well known as a next generation new material with excellent electrical, optical, and physical properties. However, as a method of separating graphene from graphite, which enables mass-production, there is a graphene oxide obtained by oxidizing graphite to expand graphite and separating graphite into more than one layer. The graphene oxide has been known up to now as an insulator through which electricity does not flow due to generation of several functional groups (—OH, —COOH, etc) caused by breaking of an inner benzene ring in an oxidation process.

Therefore, in order to actually use electrical properties as a conductor or a semiconductor, a reduced graphene oxide obtained by restoring a benzene ring using a reducing agent (HI, NH₂NH₂, etc) is prepared and used. However, the reduced graphene oxide has inferior electrical properties to graphene before being oxidized due to defects remaining without being restored.

Therefore, as transparent electrode materials used for various purposes, development of electrode materials which can replace conventional materials is urgent.

### RELATED ART DOCUMENT

### Patent Document

Patent Document 1: US Laid-open Patent No. 2010-0291438

### SUMMARY OF THE INVENTION

The present invention has been invented in order to overcome the above-described problems and it is, therefore, an object of the present invention to provide transparent electrodes of various shapes that can replace materials which constitute conventional transparent electrodes and electronic materials comprising the same.

In accordance with one aspect of the present invention to achieve the object, there is provided a transparent electrode including a substrate, a first electrode layer formed on the substrate, and a graphene oxide layer formed on and/or under the first electrode layer.

The first electrode layer may be formed of a conductor and/or a semiconductor.

When the first electrode layer is a conductor, the conductor may be formed of at least one selected from the group consisting of metal materials, carbon materials, metal oxide materials, and conductive polymers.

The metal material among the conductors may be at least one selected from the group consisting of Cu, Al, Ag, Au, Pt, Ni, Pd, Fe, Zn, and Ti.

The carbon material among the conductors may be at least one selected from the group consisting of carbon nanotube (CNT), carbon nanofiber (CNF), carbon black, graphene, fullerene, and graphite.

It is preferred that the metal oxide material among the conductors is a transparent conducting oxide.

The metal oxide may be at least one selected from the group consisting of Cd, Zn, In, Pb, Mo, W, Sb, Ti, Ag, Mn, Sn, Zr, Sr, Ga, Si, and Cr.

The conductive polymer among the conductors may be at least one selected from the group consisting of poly(3,4-ethylenedioxythiophene), polyacetylene, polyaniline, polypyrrole, polythiophene, and polysulfur nitride.

When the first electrode layer is a semiconductor, the semiconductor may be formed using at least one selected from the group consisting of germanium (Ge), silicon (Si), gallium arsenide (GaAs), and indium phosphide (InP).

Further, in accordance with various embodiments of the present invention, the first electrode layer may have at least one shape selected from the group consisting of a sheet, a particle, a wire, a fiber, a ribbon, a tube, and a grid.

Therefore, it is preferred that the graphene oxide layer is formed with a thickness of less than 100 nm considering transmittance.

It is preferred that the transparent electrode of the present invention has a surface resistance of 1,000 ohm/□.

In accordance with another aspect of the present invention to achieve the object, there is provided an electronic material comprising a transparent electrode.

The electronic material may be selected from liquid crystal displays, electronic paper displays, photoelectric elements, touch screens, organic EL elements, solar cells, fuel cells, secondary cells, supercapacitors, and electromagnetic or noise shielding layers.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1 and 2 show a structure of a transparent electrode including a graphene oxide layer in accordance with an embodiment of the present invention;

FIG. 3 shows a structure of a transparent electrode in accordance with a comparative example 1;

FIG. 4 shows a structure of a transparent electrode in accordance with an embodiment 1 of the present invention;

FIG. 5 shows a structure of a transparent electrode in accordance with an embodiment 2 of the present invention;

FIG. 6 shows the result of checking whether a graphene oxide layer is coated on a glass substrate in the transparent electrode manufactured in accordance with the embodiment 2 of the present invention;

FIG. 7 shows a structure of a transparent electrode in accordance with an embodiment 3 of the present invention;

FIG. 8 shows the result of checking whether a graphene oxide layer is coated on a glass substrate and a first electrode layer in the transparent electrode manufactured in accordance with the embodiment 3 of the present invention;

FIG. 9 is a scanning electron microscope photograph of the transparent electrode manufactured in accordance with the embodiment 3 of the present invention;

FIG. 10 shows a structure of a transparent electrode in accordance with a comparative example 3 of the present invention;

FIG. 11 shows a structure of a transparent electrode in accordance with an embodiment 4 of the present invention;

FIG. 12 shows a structure of a transparent electrode in accordance with a comparative example 4 of the present invention; and

FIG. 13 shows a structure of a transparent electrode in accordance with an embodiment 5 of the present invention.

### DETAILED DESCRIPTION OF THE PREFERABLE EMBODIMENTS

Hereinafter, the present invention will be described in detail.

Terms used herein are provided to explain specific embodiments, not limiting the present invention. Throughout this specification, the singular form includes the plural form unless the context clearly indicates otherwise. Further, terms “comprises” and/or “comprising” used herein specify the existence of described shapes, numbers, steps, operations, members, elements, and/or groups thereof, but do not preclude the existence or addition of one or more other shapes, numbers, operations, members, elements, and/or groups thereof.

The present invention relates to a transparent electrode comprising a graphene oxide layer and an electronic material comprising the same.

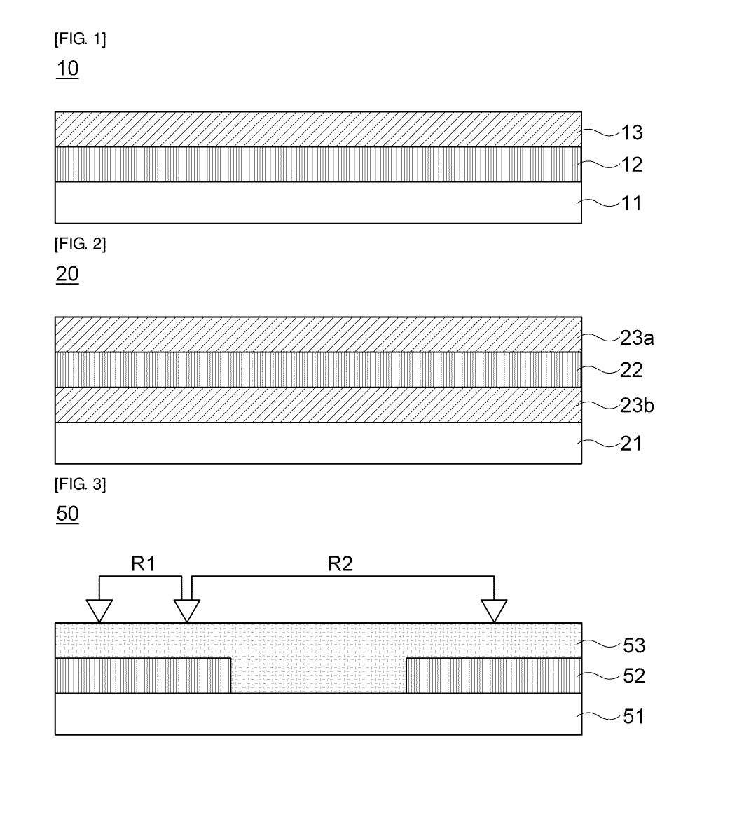

A transparent electrode 10 in accordance with an embodiment of the present invention, as shown in FIG. 1, may include a substrate 11, a first electrode layer 12 formed on the substrate 11, and a graphene oxide layer 13 formed on and/or under the first electrode layer 12.

Further, FIG. 2 shows a transparent electrode 20 in accordance with an embodiment of the present invention, which includes a substrate 21, a first electrode layer 22 formed on the substrate 21, a graphene oxide layer 23a formed on the first electrode layer 22, and a graphene oxide layer 23b formed under the first electrode layer 22. The graphene oxide layers 23a and 23b formed on and under the first electrode layer 22 overcome degradation of long-term reliability by blocking materials which are introduced into the transparent electrode from the outside to deteriorate characteristics of the transparent electrode.

The substrate 11 may use both of transparent and opaque materials, preferably, a transparent material. Further, the substrate 11 may use both of a rigid material and a flexible material.

Further, the substrate 11 may use an insulator or a semiconductor material, and among them, an insulator may be preferably used. The substrate 11 may use organic, inorganic, and organic/inorganic hybrid materials. The organic material may be polyethylene terephthalate (PET), polyacrylate, polyurethane, polycarbonate (PC), polyimide (PI), and poly methyl methacrylate (PMMA), the inorganic material may be glass, and the organic/inorganic hybrid material may be Si—OR, but they are not limited thereto.

The substrate 11 in accordance with the present invention may use the materials listed above as they are or the substrate 11 may have hydrophilicity or hydrophobicity through a predetermined pretreatment process. It may be more preferred to use a substrate having hydrophilicity through a pretreatment process in terms of improvement in adhesion between the first electrode layer 12 formed on the substrate 11 and the graphene oxide layer 13. The pretreatment process, for example, may be a plasma treatment but not particularly limited thereto, and any treatment can be used if it gives hydrophilicity.

In the transparent electrode 10 in accordance with the present invention, first, the first electrode layer 12 is formed on the substrate 11 selected from the materials listed above. At this time, the first electrode layer 12 may be formed using a conductor and/or a semiconductor. Further, the first electrode layer 12 may be formed in a plurality of layers.

In the transparent electrode 10 in accordance with an embodiment of the present invention, when the first electrode layer 12 is formed using a conductor, the conductor may be at least one selected from the group consisting of metal materials, carbon materials, metal oxide materials, and conductive polymers.

The metal material among the conductors may be at least one selected from the group consisting of Cu, Al, Ag, Au, Pt, Ni, Pd, Fe, Zn, and Ti.

Further, the carbon material among the conductors may be at least one selected from the group consisting of carbon nanotube (CNT), carbon nanofiber (CNF), carbon black, graphene, fullerene, and graphite.

Further, it is preferred that the metal oxide material among the conductors is a transparent conducting oxide.

The metal oxide may be at least one selected from the group consisting of Cd, Zn, In, Pb, Mo, W, Sb, Ti, Ag, Mn, Sn, Zr, Sr, Ga, Si, and Cr.

Further, the conductive polymer among the conductors may be at least one selected from the group consisting of poly(3,4-ethylenedioxythiophene), polyacetylene, polyaniline, polypyrrole, polythiophene, and polysulfur nitride.

In another embodiment of the present invention, when the first electrode layer 12 is a semiconductor, the semiconductor may be formed using at least one selected from germanium (Ge), silicon (Si), gallium arsenide (GaAs), and indium phosphide (InP).

Further, in accordance with embodiments of the present invention, the first electrode layer 12 may have at least one shape selected from the group consisting of a sheet, a particle, a wire, a ribbon, a tube, and a grid.

When the first electrode layer 12 in accordance with the present invention has the shape of a wire, a ribbon, or a grid, it is preferred that the material of the first electrode layer 12 is coated after being dispersed in an appropriate dispersion medium. The dispersion medium may be preferably water but not limited thereto. Further, the coating method of the first electrode layer 12 may be spin coating, spray coating, slot die coating, gravure coating, or screen printing coating but not limited thereto.

The first electrode layer 12 in accordance with the present invention is preferably formed with a thickness of less than 1 μm, more preferably less than 100 nm, in terms of transmittance.

In the present invention, a predetermined pretreatment process is performed on the first electrode layer 12 so that the first electrode layer 12 has hydrophilicity or hydrophobicity. When using the first electrode layer 12 having hydrophilicity through a pretreatment process, it is more preferred in terms of improvement in adhesion with the graphene oxide layer 13. The pretreatment process, for example, may be a plasma treatment but not particularly limited thereto, and any treatment can be used if it gives hydrophilicity.

Further, in the transparent electrode 10 in accordance with the present invention, the first electrode layer 12 is formed on the substrate 11, and the graphene oxide layer 13 is formed on the first electrode layer 12.

The graphene oxide has the shape of a sheet with a thickness of nm and is easily dispersed in a dispersion medium such as water in a monolayer state. Therefore, it is possible to form the graphene oxide layer 13 by dispersing the graphene oxide in an appropriate dispersion medium and coating the graphene oxide dispersion on the first electrode layer 13 with a well-known method such as spin coating, slot die coating, or spray coating. The graphene oxide layer 13 in accordance with the present invention, which is coated as above, is coated on the first electrode layer 12 in a nearly sheet form.

Therefore, the graphene oxide layer 13 of the present invention is characterized by performing a role of a protective layer while maintaining a surface resistance of the first electrode layer 12 as it is or without greatly increasing the surface resistance of the first electrode layer 12 (within 50%) as well as maintaining insulation with the adjacent first electrode layer 12, which is made of a conductor and/or a semiconductor.

Therefore, it is possible to overcome degradation of long-term reliability due to introduction of oxygen, moisture, and other impurities as well as to maintain a low surface resistance compared to an overcoating layer using an organic material, which is conventionally formed on the first electrode layer.

Further, in accordance with an embodiment of the present invention, when the first electrode layer has the shape of a nanowire, in case that a resistance is increased due to contact failure between nanowires by several reasons, when the graphene oxide layer is coated on the first electrode layer, the surface resistance of the first electrode layer is reduced by tightly covering the nanowire with the graphene oxide layer as in FIG. 11.

Therefore, the graphene oxide can be effectively used as a transparent electrode material by maintaining the unique surface resistance of the first electrode layer within a predetermined range regardless of the condition that the surface resistance of the first electrode layer is increased by several factors or maintained as it is.

It is preferred in terms of transmittance that the graphene oxide layer 13 in accordance with the present invention is formed with a thickness of less than 1 μm, preferably 100 nm. Further, the graphene oxide layer 13 may be formed in a multilayer structure of more than two layers, and the number of layers thereof is not particularly limited.

Therefore, since a surface resistance of the transparent electrode 10 manufactured in accordance with the present invention can be maintained at a very low level, that is, several ohms to several tens of ohms/□ according to the surface resistance of the first electrode layer, it can be preferably used as a good material that can replace conventional ITO as a transparent electrode material.

Further, the present invention is characterized by providing various electronic materials comprising the transparent electrode.

The electronic material may be selected from liquid crystal displays, electronic paper displays, photoelectric elements, touch screens, organic EL elements, solar cells, fuel cells, supercapacitors, and electromagnetic or noise shielding layers.

Hereinafter, preferred embodiments of the present invention will be described in detail. The following embodiments merely illustrate the present invention, and it should not be interpreted that the scope of the present invention is limited to the following embodiments. Further, although certain compounds are used in the following embodiments, it is apparent to those skilled in the art that equal or similar effects are shown even when using their equivalents.

### Comparative Example 1

A transparent electrode 50 having a structure of FIG. 3 is manufactured. A first electrode layer 52 is formed by applying an Ag nanowire with a surface resistance of ˜20Ω/□ on a glass substrate 51 with a bar coating method. The transparent method including an overcoating layer 53 is manufactured by applying PEDOT/PSS, a conductive polymer, on the first electrode layer 52 with a spray coating method.

### Embodiment 1

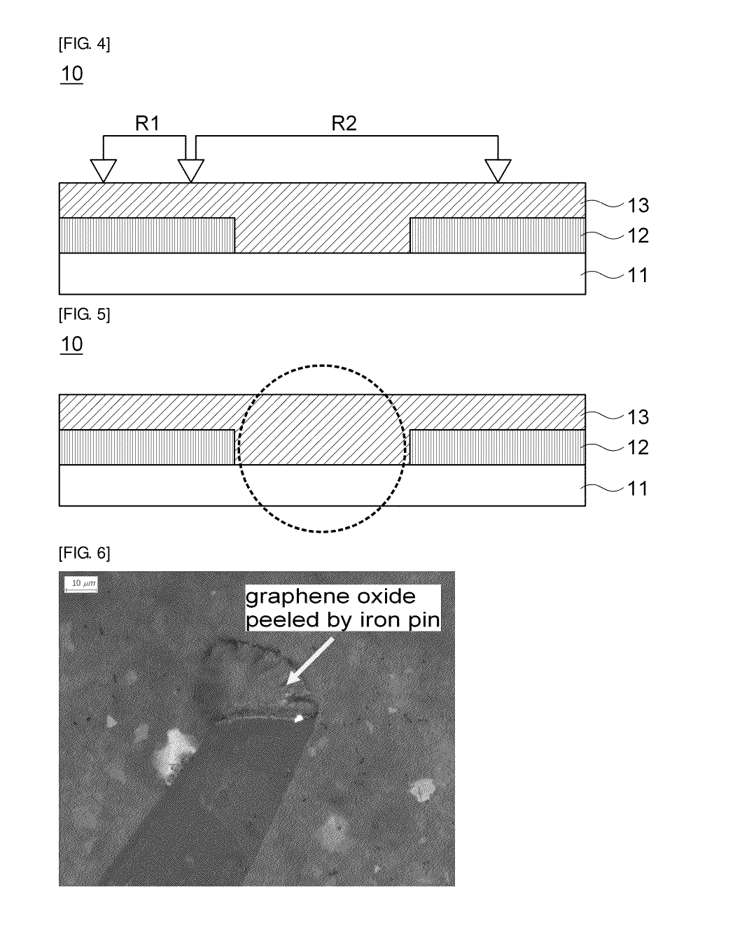

A transparent electrode 10 having a structure of FIG. 4 is manufactured. A first electrode layer 12 with a thickness of several tens of nm is formed by applying an Ag nanowire with a surface resistance of ˜20Ω/□ on a glass substrate 11 with a bar coating method.

The transparent electrode 10 including a graphene oxide layer 13 with a thickness of several tens of nm is manufactured by dispersing a graphene oxide in water and applying the graphene oxide dispersion on the first electrode layer 12 with a spray coating method.

### Experimental Example 1

Surface resistances of the transparent electrodes in accordance with the comparative example 1 and the embodiment 1 are measured using a 4-point probe as in FIGS. 3 and 4, and results thereof are arranged in Table 1.

R1 is a resistance value measured in a connection portion of the Ag nanowires, and R2 is a resistance value measured in a portion where the Ag nanowires of both sides are separated into a conductive polymer layer and a graphene oxide layer, respectively.

TABLE 1

| | First electrode layer | | |
|---|---|---|---|
| | (Ω/□) | R1 (Ω/□) | R2 (Ω/□) |
| Comparative example 1 | 20 | ~50 | ~1,000 |
| Embodiment 1 | 20 | ~20 | ∞ |

As in the results of Table 1, in case of the transparent electrode (comparative example 1) including the overcoating layer which is made of an organic material such as a conductive polymer as before, the resistance value R1 is increased about 2.5 times compared to a resistance value of the first electrode layer. That is, the surface resistance of the transparent electrode is rather increased by the coating of the conductive polymer as a conductor. Further, although the surface resistance is increased 50 times compared to the first electrode layer, R2, that is, the resistance value in the region including the conductive polymer in which the Ag nanowire is not included, is not preferred due to possibility of an electrical short since electricity continuously flows horizontally in the region of the conductive polymer although the Ag nanowire is separated by patterning.

In contrast, in case of the transparent electrode (embodiment 1) including the graphene oxide layer in accordance with the present invention, the surface resistance value of the first electrode layer and R1 are maintained with little difference. From this, it is possible to know that the graphene oxide layer between the first electrode layers as a conductor maintains characteristics of the conductor as they are. Further, it is checked that the resistance value R2 is infinite and completely shows characteristics of an insulator. From this, it is possible to know that the graphene oxide layer fully performs a role of an insulator by being positioned between the first electrode layers as a conductor.

From these results, in the transparent electrode including the graphene oxide layer in accordance with the present invention, it is possible to know that the graphene oxide layer formed on a conductor maintains the characteristics of the conductor vertically and the graphene oxide layer included between the conductors performs a role of an insulator horizontally. This is because a carrier (electron or hole) can relatively easily move vertically through a complete graphene structure (sp²) which partially remains without being broken by oxidation, but on the other hand the carrier is difficult to move horizontally when the graphene oxide is formed into a thin film with a thickness of less than 100 nm, preferably less than several tens of nm.

### Comparative Example 2

A transparent electrode including a first electrode layer with a thickness of several tens of nm is manufactured by applying an Ag nanowire with a resistance of ˜20Ω/□ on a glass substrate with a bar coating method. The comparative example 2 is a transparent electrode including only a first electrode layer on a substrate without a graphene oxide layer and used as a comparative example in order to measure the effect according to whether the graphene oxide layer exists or not.

### Embodiment 2

In manufacturing a transparent electrode 10 having a structure of FIG. 5, a first electrode layer 12 with a thickness of several tens of nm is formed by applying an Ag nanowire with a resistance of ˜20Ω/□ on a glass substrate 11 with a bar coating method.

The transparent electrode 10 including a graphene oxide layer 13 with a thickness of several tens of nm is manufactured by dispersing a graphene oxide in water and applying the graphene oxide dispersion on the first electrode layer 12 with a spray coating method.

### Experimental Example 2

Surface resistances before and after coating of the graphene oxide layer are measured by a 4-point probe and transmittance thereof are measured by a haze meter, using the transparent electrodes in accordance with the comparative example 2 and the embodiment 2, and results thereof are arranged in Table 2.

TABLE 2

| | First | Surface resistance of | |
|---|---|---|---|
| | electrode layer | graphene oxide layer | Transmittance |
| | (Ω/□) | (Ω/□) | (%) |
| Comparative | 20 | — | 90 |
| example 2 | | | |
| Embodiment 2 | 20 | ~20 | 89 |

As in the results of Table 2, in case of the transparent electrode (embodiment 2) including the graphene oxide layer in accordance with the present invention, it is possible to check that there is little difference from the surface resistance value of the first electrode layer. Further, even in case of transmittance, it is possible to check that there is no significant difference from the transmittance of the first electrode layer. Further, as in FIG. 6, it is possible to check that the graphene oxide layer is coated well on the glass substrate in the transparent electrode manufactured in accordance with the embodiment 2 of the present invention.

### Embodiment 3

A glass substrate is pretreated with plasma. A first electrode layer with a thickness of several tens of nm is formed by applying an Ag nanowire with a resistance of ˜20Ω/□ on the pretreated glass substrate with a bar coating method.

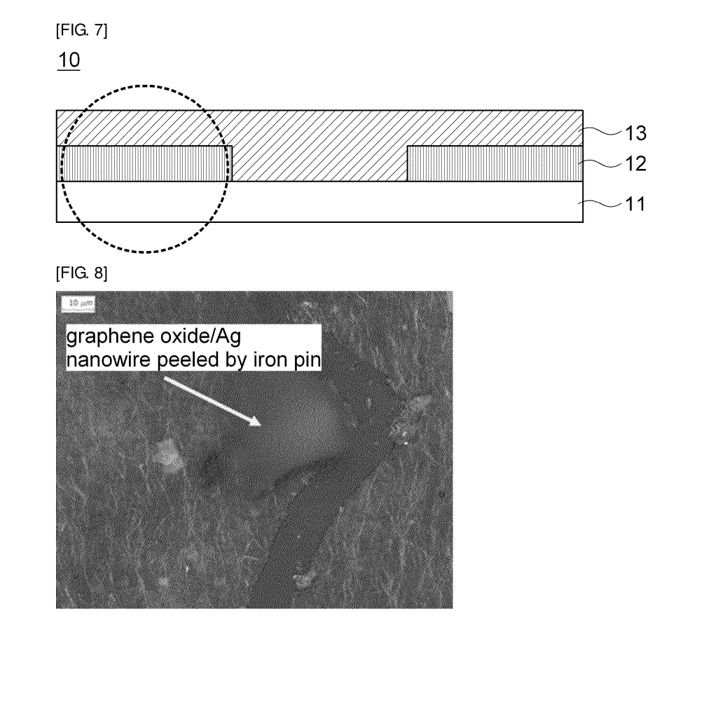

The first electrode layer is pretreated with plasma. A transparent electrode including a graphene oxide layer with a thickness of several tens of nm is manufactured by dispersing a graphene oxide in water and repeatedly applying the graphene oxide dispersion on the pretreated first electrode layer with a spray coating method. A structure of the finally manufactured electrode is as shown in FIG. 7.

### Experimental Example 3

In the transparent electrode of FIG. 7 manufactured in accordance with the embodiment 3, in order to check whether the graphene oxide layer is coated well on the glass substrate, after a circle portion of the transparent electrode is scratched by an iron pin, it is checked whether the graphene oxide layer is coated or not by an optical microscope, and results thereof are shown in FIG. 8.

As in FIG. 8, it is possible to check that the graphene oxide layer is sufficiently coated on the glass substrate, by checking the graphene oxide peeled by the iron pin.

### Experimental Example 4

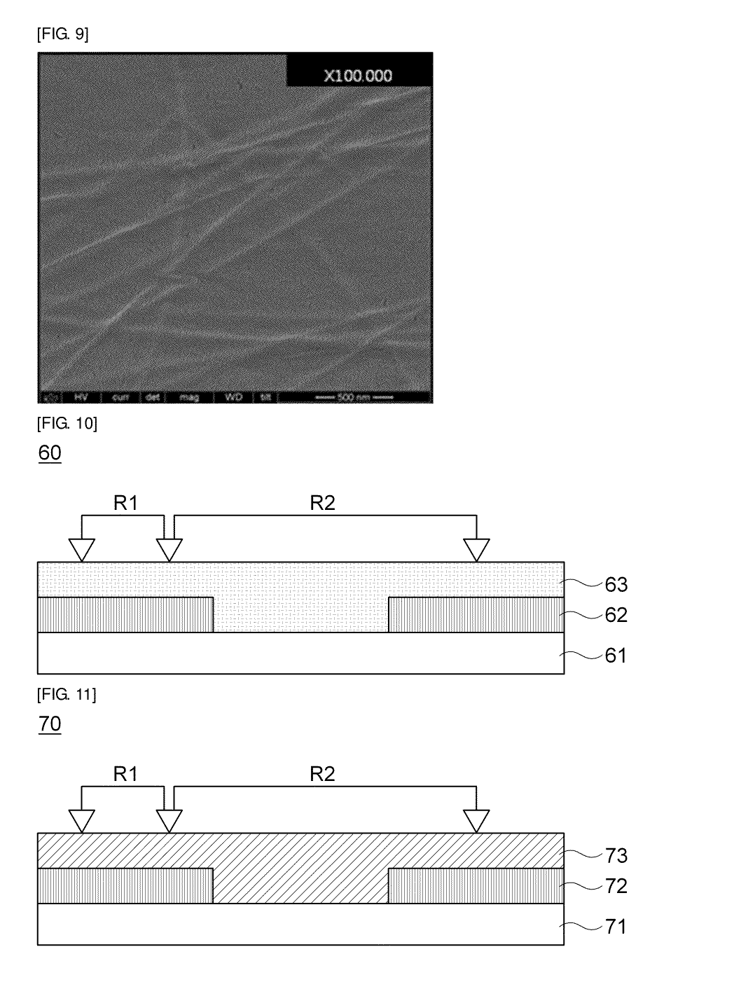

A scanning electron microscope photograph of the transparent electrode in accordance with FIG. 7 is checked, and results thereof are shown in FIG. 9.

As in FIG. 9, it is possible to check that the graphene oxide layer covers the Ag nanowire.

### Comparative Example 3

As in FIG. 10, a first electrode layer 62 with a thickness of several um is formed by applying copper metal on a glass substrate 61. A transparent electrode 60 including an overcoating layer 63 is manufactured by applying PEDOT/PSS, a conductive polymer, on the first electrode layer 62.

### Embodiment 4

As in FIG. 11, a first electrode layer 72 with a thickness of several um is formed by applying copper metal on a glass substrate 71. A transparent electrode 70 including a graphene oxide layer 73 is manufactured by dispersing a graphene oxide in water and applying the graphene oxide dispersion on the first electrode layer 72.

### Experimental Example 5

Surface resistances of the transparent electrodes in accordance with the comparative example 3 and the embodiment 4 are measured by a 4-point probe as in FIGS. 10 and 11, and results thereof are arranged in Table 3.

R1 is a resistance value measured in a connection portion of Ag nanowires, and R2 is a resistance value measured when the Ag nanowires of both sides are separated into a conductive polymer layer and a graphene oxide layer, respectively.

TABLE 3

| | First electrode layer | | |
|---|---|---|---|
| | (Ω/cm) | R1 (Ω/cm) | R2 (Ω/cm) |
| Comparative example 3 | 10⁻¹ | ~600 | ~1,000 |
| Embodiment 4 | 10⁻¹ | 10⁻¹ | ∞ |

As in the results of Table 3, it is possible to check that the same effect as the embodiment 1 can be obtained using a graphene oxide even when the first electrode layer is made of a metal bulk (copper metal), not an Ag nanowire as in the embodiment 3.

### Comparative Example 4

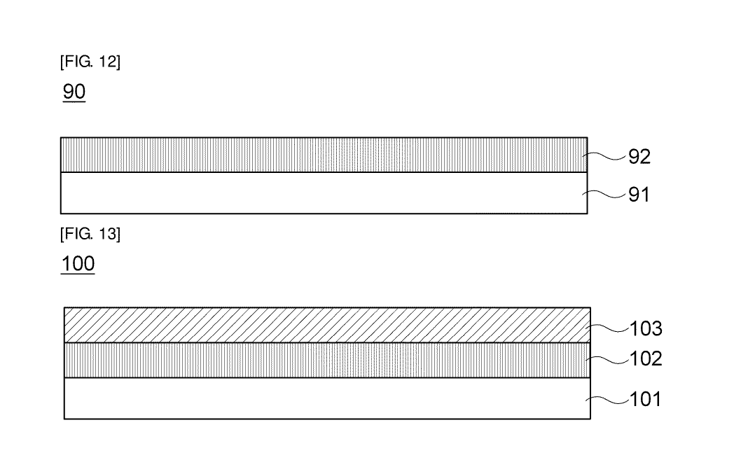

As in FIG. 12, a transparent electrode 90 is manufactured by applying an Ag nanowire on a PET substrate 91 to form a first electrode layer 92 with a thickness of several tens of nm.

### Embodiment 5

As in FIG. 13, a transparent electrode 100 including a graphene oxide layer 103 on a first electrode layer 102 is manufactured by applying an Ag nanowire on a PET substrate 101 to form a first electrode layer 102 with a thickness of several tens of nm. A plasma treatment is performed before all coating.

### Experimental Example 6

Surface resistances of the transparent electrodes in accordance with the comparative example 4 and the embodiment 5 are measured by a 4-point probe before and after a reliability test (85/85-85° C./humidity 85%, 120 hours), and results thereof are arranged in Table 5.

TABLE 5

| | Before reliability test (Ω/□) | After reliability test (Ω/□) |
|---|---|---|
| Comparative | 27 | Measurement x (∞) |
| example 4 | | |
| Embodiment 6 | 27 | 34 |

As in the results of Table 5, when the graphene oxide layer is formed on the PET substrate, changes in surface resistance after the reliability test are reduced. From this, it is possible to check that the graphene oxide layer protects the first electrode layer by blocking the materials introduced into the first electrode layer from the outside, thereby improving long-term reliability. From this result, it is possible to check that the graphene oxide layer in accordance with the present invention also performs as a barrier layer for protecting the first electrode layer.

The transparent electrode according to the present invention includes graphene oxide layers on and under a conductor and/or a semiconductor to maintain a resistance measured on a surface of a graphene oxide layer in a transparent electrode including the graphene oxide layer almost equal to a resistance of a conductor and/or a semiconductor while showing characteristics of an insulator between conductors or semiconductors or between a conductor and a semiconductor which are separated from each other. Further, the graphene oxide layer performs a role of a barrier layer to protect the transparent electrode, thus preventing deterioration of characteristics of the transparent electrode.

Therefore, the transparent electrode including the graphene oxide layer can be used as an excellent material without chemical and electrical defects that can replace conventional materials such as ITO and silicon.

What is claimed is:

1. A transparent electrode comprising:
a substrate,
a first electrode layer formed on the substrate, and
a graphene oxide layer formed on and/or under the first electrode layer.

2. The transparent electrode according to claim 1, wherein the first electrode layer is formed of a conductor and/or a semiconductor.

3. The transparent electrode according to claim 2, wherein the conductor is at least one selected from the group consisting of metal materials, carbon materials, metal oxide materials, and conductive polymers.

4. The transparent electrode according to claim 3, wherein the metal material is at least one selected from the group consisting of Cu, Al, Ag, Au, Pt, Ni, Pd, Fe, Zn, and Ti.

5. The transparent electrode according to claim 3, wherein the carbon material is at least one selected from the group consisting of carbon nanotube (CNT), carbon nanofiber (CNF), carbon black, graphene, fullerene, and graphite.

6. The transparent electrode according to claim 3, wherein the metal oxide material is a transparent conducting oxide.

7. The transparent electrode according to claim 6, wherein a metal of the metal oxide material is at least one selected from the group consisting of Cd, Zn, In, Pb, Mo, W, Sb, Ti, Ag, Mn, Sn, Zr, Sr, Ga, Si, and Cr.

8. The transparent electrode according to claim 3, wherein the conductive polymer is at least one selected from the group consisting of poly(3,4-ethylenedioxythiophene), polyacetylene, polyaniline, polypyrrole, polythiophene, and polysulfur nitride.

9. The transparent electrode according to claim 2, wherein the semiconductor is at least one selected from the group consisting of germanium (Ge), silicon (Si), gallium arsenide (GaAs), and indium phosphide (InP).

10. The transparent electrode according to claim 1, wherein the first electrode layer has at least one shape selected from the group consisting of a sheet, a particle, a nanowire, a fiber, a ribbon, a tube, and a grid.

11. The transparent electrode according to claim 1, wherein the graphene oxide layer is formed with a thickness of less than 100 nm.

12. The transparent electrode according to claim 1, wherein the transparent electrode has a surface resistance of less than 1,000 ohm/□.

13. An electronic material comprising a transparent electrode according to claim 1.

14. The electronic material according to claim 13, wherein the electronic material is a liquid crystal display, an electronic paper display, a photoelectric element, a touch screen, an organic E/L element, a solar cell, a fuel cell, a secondary cell, a supercapacitor, an electromagnetic shielding layer, or a noise shielding layer.
